(19) United States
(12) Patent Application Publication
(10) Pub. No.: US 2025/0255019 A1
(43) Pub. Date: Aug. 7, 2025

(54) SENSOR PACKAGE STRUCTURE HAVING WIRELESS CONFIGURATION AND MANUFACTURING METHOD THEREOF

(71) Applicant: TONG HSING ELECTRONIC INDUSTRIES, LTD., Taipei City (TW)

(72) Inventors: DONG-RU WU, Hsin-Chu County (TW); LI-CHUN HUNG, Hsin-Chu County (TW)

(21) Appl. No.: 18/678,253

(22) Filed: May 30, 2024

(30) Foreign Application Priority Data
Feb. 1, 2024 (TW) 113103860

(51) Int. Cl. H01L 27/146; H01L 23/00

(52) U.S. Cl. CPC H10F 39/804; H01L 24/08; H01L 24/16; H01L 24/32; H01L 24/73; H01L 24/97; H10F 39/011; H10F 39/811; H01L 2224/08225; H01L 2224/16227; H01L 2224/32225; H01L 2224/73204; H01L 2224/97

(57) ABSTRACT

A sensor package structure having a wireless configuration includes a substrate, a sensing module, and a cap. The substrate has a chip-bonding region and a connection region that surrounds the chip-bonding region. The sensing module includes an interposer mounted onto the chip-bonding region and a sensor chip that is stacked and mounted onto the interposer, such that the sensing module and the substrate are jointly formed as a CoWoS (chip on wafer on substrate) component. The cap includes a light-permeable sheet and a ring-shaped molding frame that is formed on the light-permeable sheet and that has a connection end arranged away from light-permeable sheet. The cap is adhered and fixed to the connection region of the substrate through the connection end, so that the substrate and the cap jointly define an enclosed space that receives the sensing module therein.

### CROSS-REFERENCE TO RELATED PATENT APPLICATION

This application claims the benefit of priority to Taiwan Patent Application No. 113103860, filed on Feb. 1, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a sensor package structure, and more particularly to a sensor package structure having a wireless configuration and a manufacturing method thereof.

### BACKGROUND OF THE DISCLOSURE

In a conventional sensor package structure, a substrate and a sensor chip are electrically coupled to each other through metal wires in a wire-bonding manner. However, a spacing between a sensing region and an outer edge of the sensor chip is designed to be smaller and smaller, such that a part of each of the metal wires needs to be embedded in an adhesive layer arranged between the sensor chip and a glass board. Moreover, the adhesive layer and the part of each of the metal wires can easily crack or become detached from each other, thereby affecting the electrical connection between the substrate and the sensor chip.

### SUMMARY OF THE DISCLOSURE

In response to the above-referenced technical inadequacies, the present disclosure provides a sensor package structure having a wireless configuration and a manufacturing method thereof for effectively improving on the issues associated with conventional sensor package structures.

In order to solve the above-mentioned problems, one of the technical aspects adopted by the present disclosure is to provide a manufacturing method of a sensor package structure having a wireless configuration. The manufacturing method includes a preparing step, a molding step, a chip-bonding step, a packaging step, and a cutting step. The preparing step is implemented by placing a mold onto a substrate layer to jointly define a formation space. The substrate layer defines a plurality of substrates. The molding step is implemented by injecting an adhesive into the formation space to form a frame layer on the substrate layer. The frame layer defines a plurality of ring-shaped molding frames respectively formed on the substrates, and each of the substrates and a corresponding one of the ring-shaped molding frames are jointly defined as one of a plurality of carrying bases. In each of the carrying bases, the substrate has a chip-bonding region surrounded by the ring-shaped molding frame, and the ring-shaped molding frame has a connection end arranged away from the substrate. The chip-bonding step is implemented by respectively mounting a plurality of sensing modules onto the chip-bonding regions of the substrates, such that each of the sensing modules and a corresponding one of the substrates are jointly formed as a CoWoS (Chip on Wafer on Substrate) component. Each of the sensing modules includes an interposer stacked and mounted on the chip-bonding region of the corresponding substrate, and a sensor chip that is stacked and mounted on the interposer. The packaging step is implemented by respectively adhering a plurality of light-permeable sheets onto the connection ends of the carrying bases, such that each of the carrying bases and a corresponding one of the light-permeable sheets jointly define an enclosed space that receives a corresponding one of the sensing modules therein. The cutting step is implemented by cutting the substrate layer and the frame layer to separate the carrying bases from each other.

In order to solve the above-mentioned problems, another one of the technical aspects adopted by the present disclosure is to provide a sensor package structure having a wireless configuration. The sensor package structure includes a carrying base, a sensing module, and a light-permeable sheet. The carrying base includes a substrate and a ring-shaped molding frame. The substrate has a chip-bonding region and a molding region that surrounds the chip-bonding region. The ring-shaped molding frame is formed on the molding region of the substrate. The ring-shaped molding frame has a connection end arranged away from the substrate. The sensing module includes an interposer stacked and mounted on the chip-bonding region and a sensor chip that is stacked and mounted on the interposer. The sensing module and the substrate are jointly formed as a CoWoS component. The light-permeable sheet is adhered and fixed to the connection end of the carrying base. The carrying base and the light-permeable sheet jointly define an enclosed space that receives the sensing module therein.

In order to solve the above-mentioned problems, yet another one of the technical aspects adopted by the present disclosure is to provide a manufacturing method of a sensor package structure having a wireless configuration. The manufacturing method includes a preparing step, a molding step, a cutting step, a chip-bonding step, and a packaging step. The preparing step is implemented by placing a mold onto a light-permeable layer to jointly define a formation space. The molding step is implemented by injecting an adhesive into the formation space to form a frame layer on the light-permeable layer. The cutting step is implemented by cutting the light-permeable layer and the frame layer to form a plurality of light-permeable sheets separated from each other and a plurality of ring-shaped molding frames that are respectively fixed on the light-permeable sheets. Each of the light-permeable sheets and a corresponding one of the ring-shaped molding frames are jointly defined as a cap, and each of the ring-shaped molding frames has a connection end arranged away from the corresponding light-permeable sheet. The chip-bonding step is implemented by mounting a sensing module onto a chip-bonding region of a substrate to be jointly formed as a CoWoS (Chip on Wafer on Substrate) component. The sensing module includes an interposer stacked and mounted on the chip-bonding region and a sensor chip that is stacked and mounted on the interposer. The packaging step is implemented by adhering the connection end of the cap onto the substrate, such that the substrate and the cap jointly define an enclosed space that receives the sensing module therein.

In order to solve the above-mentioned problems, still another one of the technical aspects adopted by the present disclosure is to provide a sensor package structure having a wireless configuration. The sensor package structure includes a substrate, a sensing module, and a cap. The substrate has a chip-bonding region and a connection region that surrounds the chip-bonding region. The sensing module includes an interposer mounted on the chip-bonding region and a sensor chip that is stacked and mounted on the interposer. The sensing module and the substrate are jointly formed as a CoWoS component. The cap includes a light-permeable sheet and a ring-shaped molding frame that is formed on the light-permeable sheet. The ring-shaped molding frame has a connection end arranged away from the light-permeable sheet. The connection end of the light-permeable sheet is adhered and fixed to the connection region of the substrate, and the substrate and the cap jointly define an enclosed space that receives the sensing module therein.

Therefore, the sensor package structure and the manufacturing method thereof in the present disclosure can be provided with the wireless configuration through the CoWoS component, thereby reducing a distance between the sensing region and the outer edge of the sensor chip (e.g., the sensor chip of the CoWoS component is provided without any pad on the top surface thereof, such that the distance can be reduced to be less than 200 μm), and effectively avoiding defects caused by metal wires.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a manufacturing method of a sensor package structure having a wireless configuration according to a first embodiment of the present disclosure;

FIG. 2 is a schematic view showing a preparing step of FIG. 1;

FIG. 3 and FIG. 4 are schematic views showing a molding step of FIG. 1;

FIG. 5 is a schematic perspective view of FIG. 4;

FIG. 6 and FIG. 7 are schematic views showing a connecting step of FIG. 1;

FIG. 8 is a schematic view showing a slicing step of FIG. 1;

FIG. 9 is a schematic view showing a chip-bonding step of FIG. 1;

FIG. 10 is a schematic view showing a packaging step of FIG. 1;

FIG. 11 and FIG. 12 are schematic views showing a cutting step of FIG. 1;

FIG. 13 is a flowchart of the manufacturing method according to a second embodiment of the present disclosure;

FIG. 14 is a schematic view showing a preparing step of FIG. 13;

FIG. 15 and FIG. 16 are schematic views showing a molding step of FIG. 13;

FIG. 17 is a schematic view showing a cutting step of FIG. 13; and

FIG. 18 and FIG. 19 are schematic views showing a chip-bonding step and a packaging step of FIG. 13.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

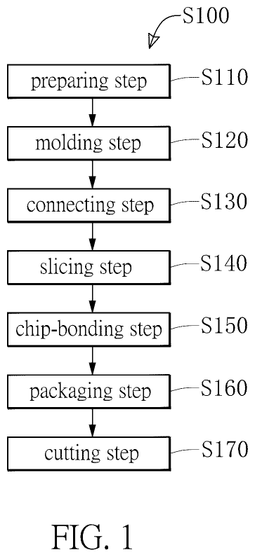

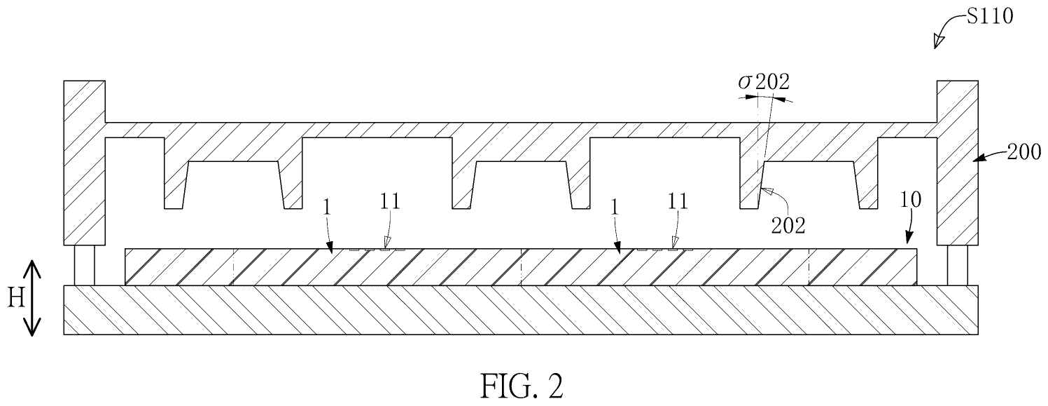

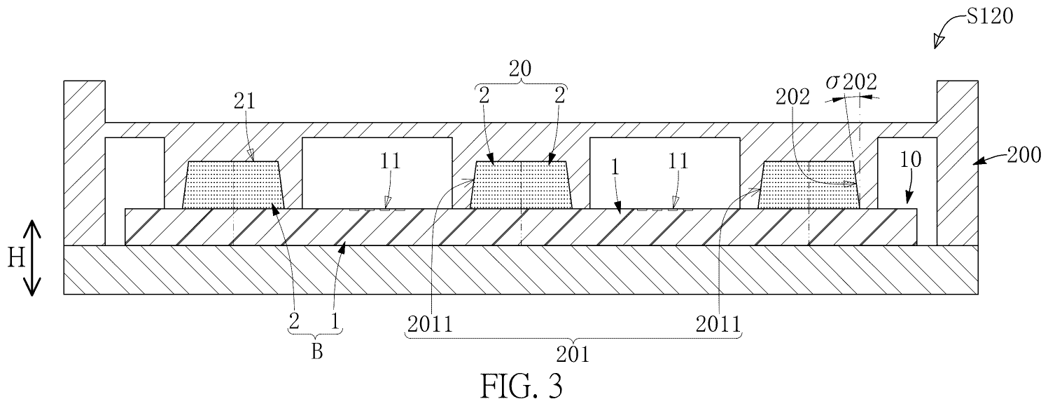

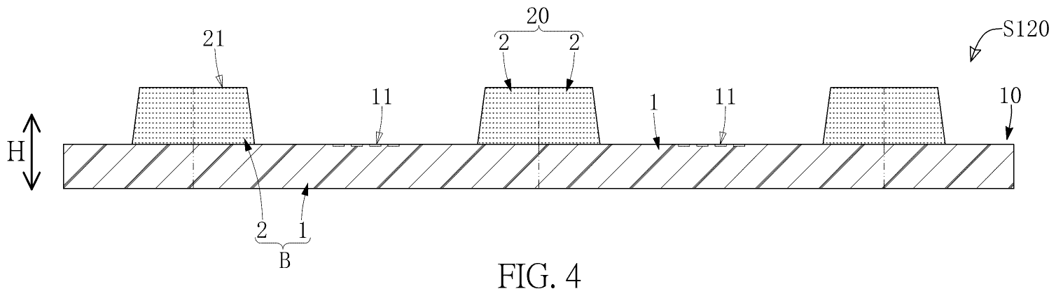

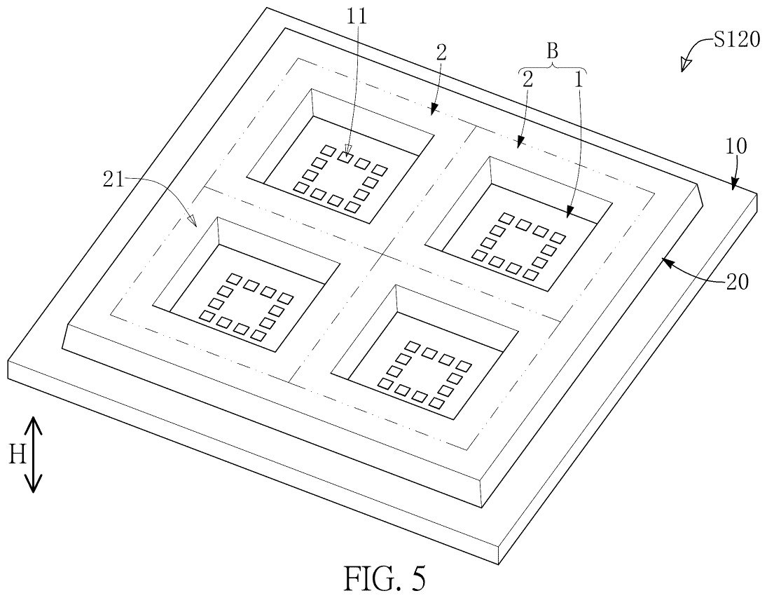

Referring to FIG. 1 to FIG. 12, a first embodiment of the present disclosure provides a sensor package structure 100 having a wireless configuration and a manufacturing method S100 thereof. In order to clearly describe the present embodiment, the following description discloses the manufacturing method S100, and then discloses the structure and connection relationship of components of the sensor package structure 100.

The manufacturing method S100 provided by the present embodiment sequentially includes (or implements) a preparing step S110, a molding step S120, a connecting step S130, a slicing step S140, a chip-bonding step S150, a packaging step S160, and a cutting step S170. The following description sequentially describes the above steps S110 to S170 of the manufacturing method S100, and the sensor package structure 100 can be produced by implementing the above steps S110 to S170, but the present disclosure is not limited thereto.

For example, in other embodiments of the present disclosure not shown in the drawings, the steps S110 to S170 of the manufacturing method S100 can be added, canceled, or adjusted according to design requirements; or, the sensor package structure 100 can be produced by implementing a method other than the manufacturing method S100 that is provided by the present embodiment.

As shown in FIG. 1 to FIG. 3, the preparing step S110 is implemented by placing a mold 200 onto a substrate layer 10 along a height direction H to jointly define a formation space 201. The substrate layer 10 defines a plurality of substrates 1. The substrates 1 in the present embodiment are connected to each other and are in a matrix arrangement, and the formation space 201 has a plurality of sub-spaces 2011 in spatial communication with each other, but the present disclosure is not limited thereto. For example, in other embodiments of the present disclosure not shown in the drawings, the substrates 1 cannot be in a matrix arrangement; or, the sub-spaces 2011 of the formation space 201 are isolated from each other (i.e., the sub-spaces 2011 are not in spatial communication with each other).

Moreover, the mold 200 in the present embodiment has a plurality of side walls 202, and each of the side walls 202 and the height direction H have a demolding angle σ202 therebetween that is within a range from 5 degrees to 7 degrees, thereby facilitating a demolding process in the following molding step S120. Specifically, a distance between any two of the side walls 202 in one of the sub-spaces 2011 gradually decreases in a direction away from the substrate layer 10.

As shown in FIG. 1 and FIG. 3 to FIG. 5, the molding step S120 is implemented by injecting an adhesive into the formation space 201 to form a frame layer 20 on the substrate layer 10. The frame layer 20 defines a plurality of ring-shaped molding frames 2 respectively formed on the substrates 1. Moreover, the ring-shaped molding frames 2 in the present embodiment are connected to each other, but the present disclosure is not limited thereto. For example, in other embodiments of the present disclosure not shown in the drawings, the ring-shaped molding frames 2 can be separated from each other. In other words, each of the sub-spaces 2011 is provided with one of the ring-shaped molding frames 2 formed therein.

It should be noted that each of the substrates 1 and a corresponding one of the ring-shaped molding frames 2 are jointly defined as one of a plurality of carrying bases B. In each of the carrying bases B, the substrate 1 has a chip-bonding region 11 surrounded by the ring-shaped molding frame 2, and the ring-shaped molding frame 2 has a connection end 21 arranged away from the substrate 1.

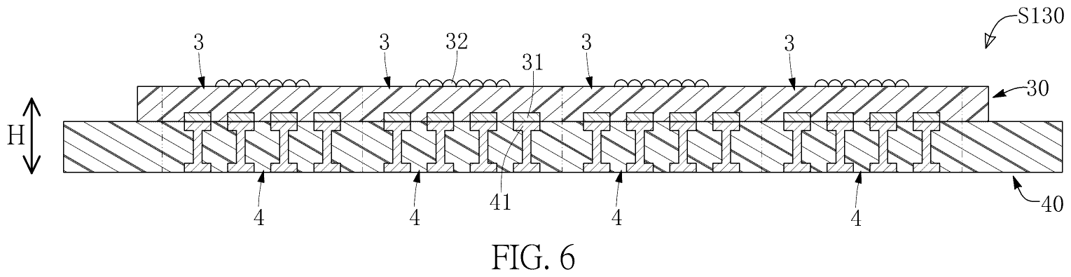

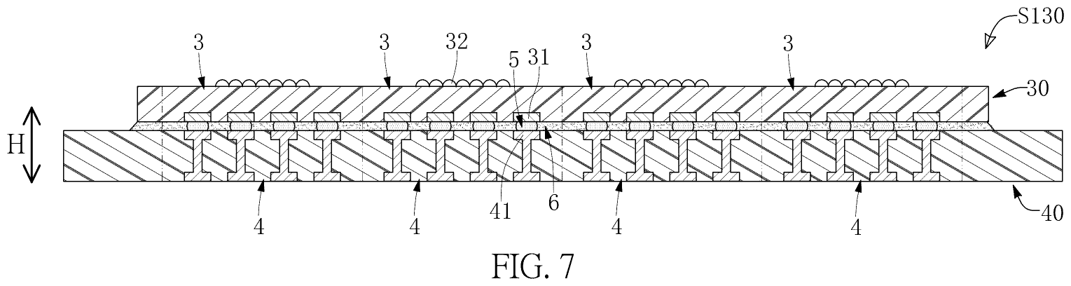

As shown in FIG. 1, FIG. 6, and FIG. 7, the connecting step S130 is implemented by mounting a wafer 30 onto an interposer layer 40. The wafer 30 defines a plurality of sensor chips 3 in a matrix arrangement, the interposer layer 40 defines a plurality of interposers 4, and the sensor chips 3 are respectively stacked and mounted onto the interposers 4.

In the present embodiment, an assembling manner between each of the sensor chips 3 and the corresponding interposer 4 can be adjusted or changed according to practical requirements. For example, as shown in FIG. 6, connection pads 31 of the sensor chip 3 and contacts 41 of the interposer 4 are fixed and electrically coupled to each other in a hybrid bonding manner. In other words, the connection pads 31 of the sensor chip 3 and the contacts 41 of the interposer 4 are connected to each other without any component arranged therebetween.

Moreover, as shown in FIG. 7, each of the sensor chips 3 and the corresponding interposer 4 are fixed to each other through a plurality of micro-bumps 5 and an underfill layer 6 arranged therebetween. The sensor chip 3 (e.g., the connection pads 31) and the interposer 4 (e.g., the contacts 41) are electrically coupled to each other through the micro-bumps 5, and the micro-bumps 5 are embedded in the underfill layer 6.

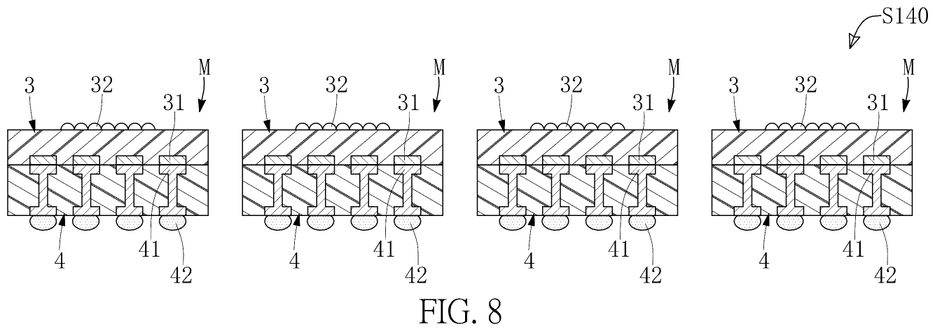

As shown in FIG. 1, FIG. 7, and FIG. 8, the slicing step S140 is implemented by slicing the interposer layer 40 and the wafer 30 to form the interposers 4 separated from each other and the sensor chips 3 that are separated from each other and that are respectively fixed to the interposers 4. Moreover, each of the interposers 4 and the corresponding sensor chip 3 fixed thereon are jointly defined as one of a plurality of sensing modules M.

In addition, the connecting step S130 and the slicing step S140 in the present embodiment are arranged between the molding step S120 and the chip-bonding step S150, but the present disclosure is not limited thereto. In other words, the connecting step S130 and the slicing step S140 are only required to be implemented before the chip-bonding step S150 according to practical requirements.

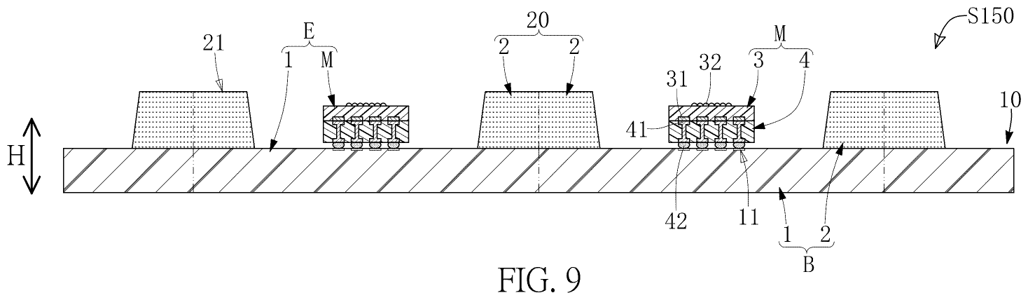

As shown in FIG. 1 and FIG. 9, the chip-bonding step S150 is implemented by respectively mounting the sensing modules M onto the chip-bonding regions 11 of the carrying bases B, such that each of the sensing modules M and a corresponding one of the substrates 1 are jointly formed as a CoWoS (Chip on Wafer on Substrate) component E. In the present embodiment, the connection end 21 of the ring-shaped molding frame 2 of each of the carrying bases B is preferably not lower than a top end of the corresponding sensing module M (e.g., a top surface of the sensor chip 3), thereby facilitating the implementation of the following packaging step S160.

Moreover, the interposer 4 of each of the sensing modules M is provided with a plurality of solder balls 42 disposed on a bottom surface thereof, and each of the sensing modules M is mounted on the chip-bonding region 11 of the corresponding carrying base B through the solder balls 42.

It should be noted that the manufacturing method S100 is limited to using the CoWoS component E for achieving the wireless configuration, thereby reducing a distance between a sensing region 32 and an outer edge of the sensor chip 3 (e.g., the sensor chip 3 of the CoWoS component E is provided without any pad on the top surface thereof, such that the distance can be reduced to be less than 200 μm). Accordingly, any manufacturing method not using the CoWoS component is different from the manufacturing method S100 provided by the present embodiment.

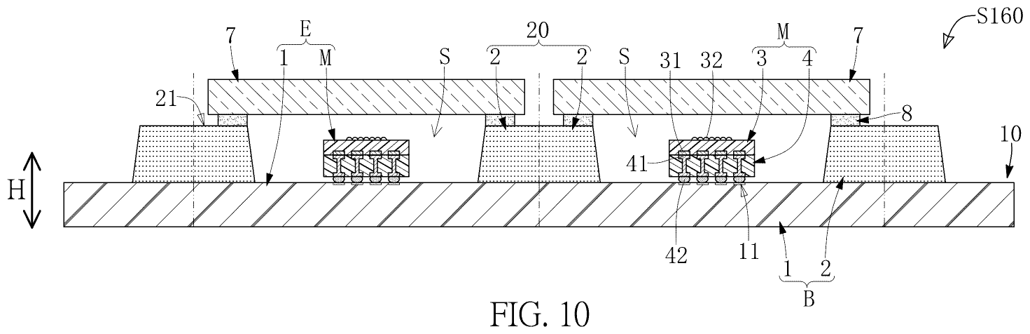

As shown in FIG. 1 and FIG. 10, the packaging step S160 is implemented by respectively adhering a plurality of light-permeable sheets 7 onto the connection ends 21 of the carrying bases B, such that each of the carrying bases B and a corresponding one of the light-permeable sheets 7 jointly define an enclosed space S that receives a corresponding one of the sensing modules M therein. The connection between each of the light-permeable sheets 7 and the connection end 21 of the corresponding carrying base B is established through an adhesive layer 8, and the adhesive layer 8 can be a light-curing glue (e.g., a UV glue), a thermal-curing glue, or an adhesive sheet, but the present disclosure is not limited thereto.

Moreover, the light-permeable sheet 7 is parallel to the substrate 1 of the carrying base B, and the light-permeable sheet 7 in the present embodiment can be a flat glass sheet and preferably has a broadband anti-reflection (BBAR) coating film formed on an outer surface thereof, but the present disclosure is not limited thereto.

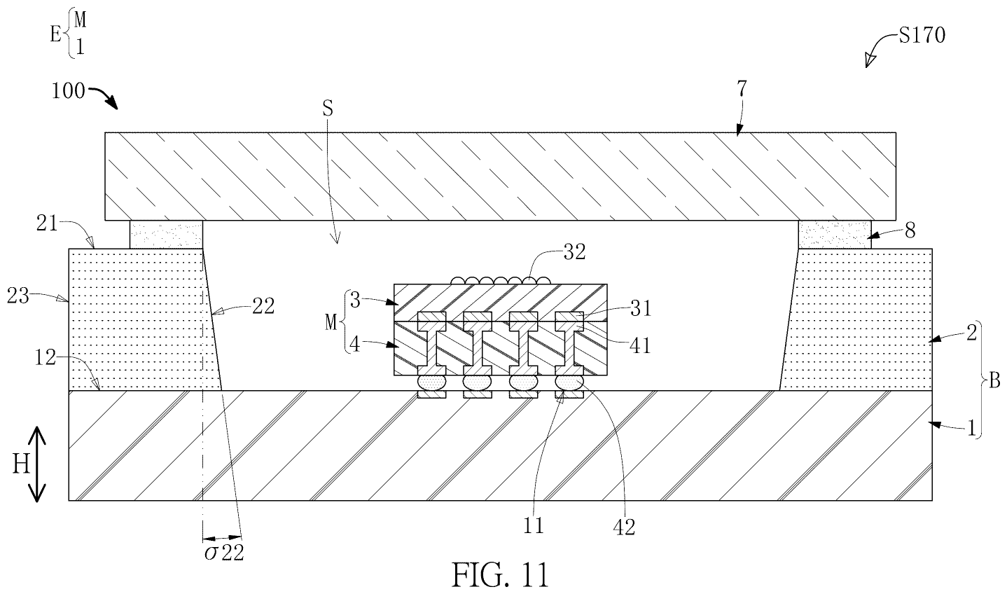

As shown in FIG. 1, FIG. 10, and FIG. 11, the cutting step S170 is implemented by cutting the substrate layer 10 and the frame layer 20 to separate the carrying bases B from each other, thereby forming a plurality of sensor package structures 100 separated from each other.

In summary, the above description of the present embodiment substantially describes an exemplary implementation of the manufacturing method S100, and the following description substantially describes the sensor package structure 100 produced by implementing the manufacturing method S100. In other words, at least part of features of the sensor package structure 100 can be referred to in the above description of the manufacturing method S100, but the present disclosure is not limited thereto.

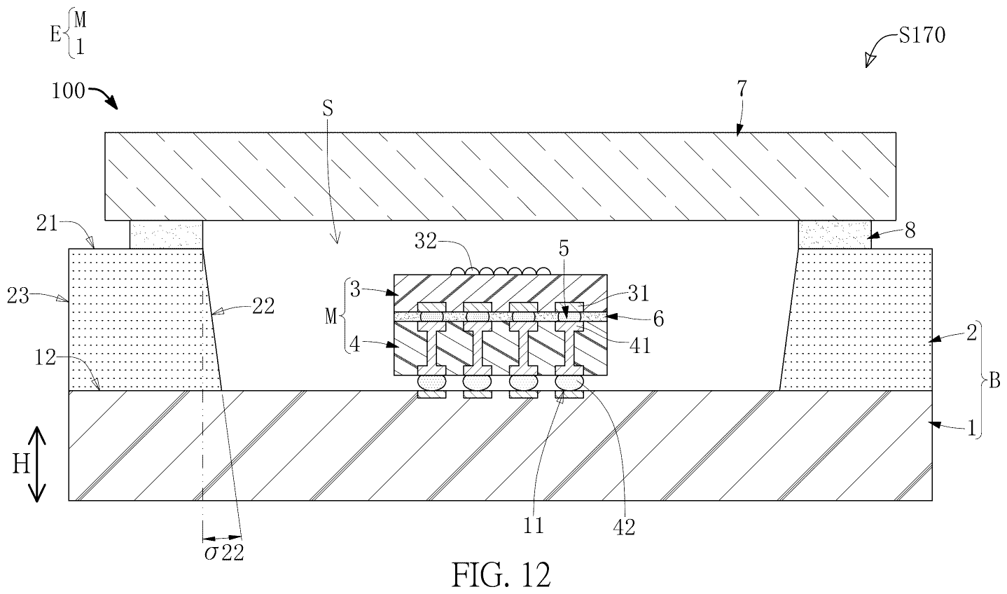

As shown in FIG. 11 and FIG. 12, the sensor package structure 100 includes a carrying base B, a sensing module M assembled in the carrying base B, and a light-permeable sheet 7 that is fixed to the carrying base B. The carrying base B includes a substrate 1 and a ring-shaped molding frame 2 that is formed on the substrate 1, and the substrate 1 is flat and has a chip-bonding region 11 and a molding region 12 that surrounds the chip-bonding region 11 and that has a rectangular ring-shape.

Moreover, the ring-shaped molding frame 2 preferably has a rectangular ring-shape and is formed on the molding region 12 of the substrate 1, and the ring-shaped molding frame 2 has a connection end 21 arranged away from the substrate 1. Specifically, the carrying base B defines a height direction H perpendicular to the chip-bonding region 11, an inner side surface 22 of the ring-shaped molding frame 2 and the height direction H have a slanting angle σ22 therebetween that is within a range from 5 degrees to 7 degrees, and an outer side surface 23 of the ring-shaped molding frame 2 is coplanar with an outer edge of the substrate 1.

The sensing module M includes an interposer 4 and a sensor chip 3 that is stacked and mounted on the interposer 4. The assembling manner of the sensor chip 3 and the interposer 4 can be adjusted or changed according to practical requirements. For example, as shown in FIG. 11, connection pads 31 of the sensor chip 3 and contacts 41 of the interposer 4 are fixed and electrically coupled to each other in a hybrid bonding manner. Or, as shown in FIG. 12, the sensing module M includes a plurality of micro-bumps 5 and an underfill layer 6, the micro-bumps 5 and the underfill layer 6 are arranged between the sensor chip 3 and the interposer 4, the sensor chip 3 and the interposer 4 are electrically coupled to each other through the micro-bumps 5, and the micro-bumps 5 are embedded in the underfill layer 6.

The sensing module M is stacked and mounted on the chip-bonding region 11 through the interposer 4, such that the sensing module M and the substrate 1 are jointly formed as a CoWoS component E. The sensing module M is preferably spaced apart from the inner side surface 22 of the ring-shaped molding frame 2, and a top end of the sensing module M is lower than the connection end 21 of the ring-shaped molding frame 2 with respect to the substrate 1.

The light-permeable sheet 7 is adhered and fixed to the connection end 21 of the carrying base B, and the carrying base B and the light-permeable sheet 7 jointly define an enclosed space S that receives the sensing module M therein. The connection between the light-permeable sheet 7 and the connection end 21 of the carrying base B in the sensor package structure 100 is established through an adhesive layer 8, and the adhesive layer 8 can be a light-curing glue (e.g., a UV glue), a thermal-curing glue, or an adhesive sheet, but the present disclosure is not limited thereto.

### Second Embodiment

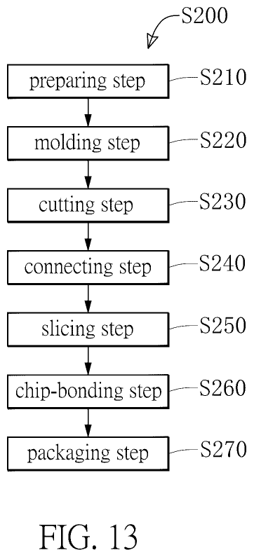

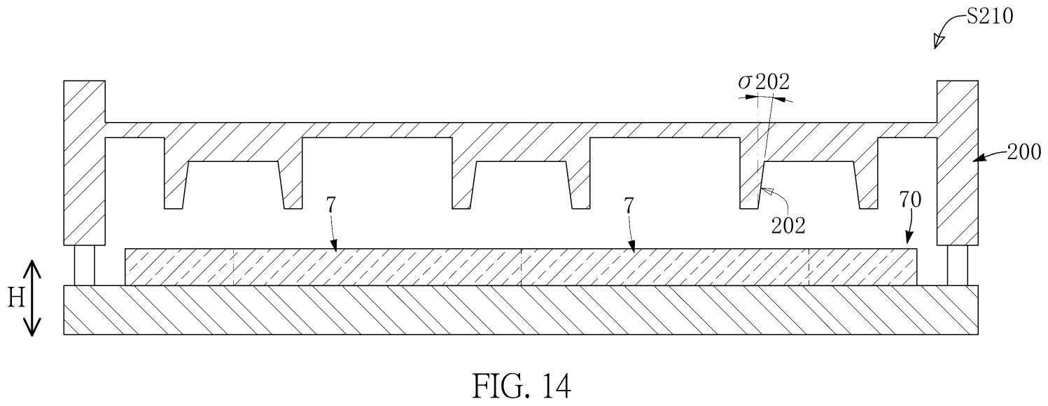

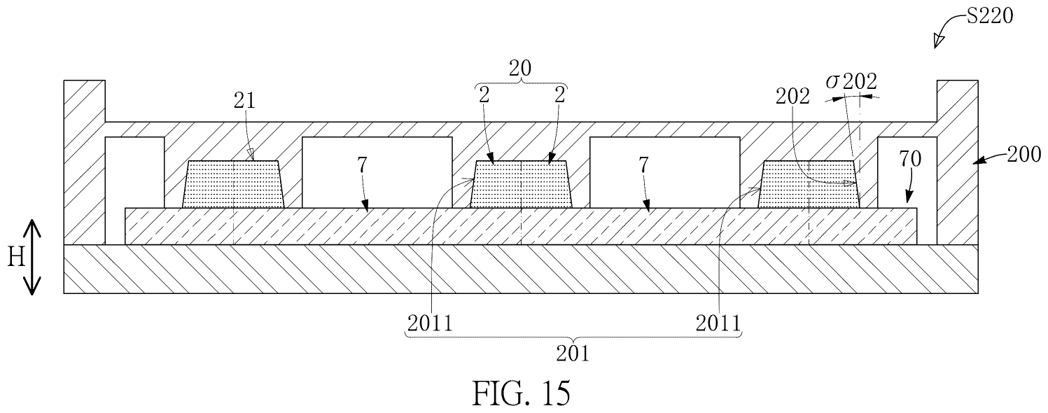

Referring to FIG. 13 to FIG. 19, a second embodiment of the present disclosure provides a sensor package structure 100 having a wireless configuration and a manufacturing method S200 thereof. In order to clearly describe the present embodiment, the following description discloses the manufacturing method S200, and then discloses the structure and connection relationship of components of the sensor package structure 100.

The manufacturing method S200 provided by the present embodiment sequentially includes (or implements) a preparing step S210, a molding step S220, a cutting step S230, a connecting step S240, a slicing step S250, a chip-bonding step S260, and a packaging step S270. The following description sequentially describes the above steps S210 to S270 of the manufacturing method S200, and the sensor package structure 100 can be produced by implementing the above steps S210 to S270, but the present disclosure is not limited thereto.

For example, in other embodiments of the present disclosure not shown in the drawings, the steps S210 to S270 of the manufacturing method S200 can be added, canceled, or adjusted according to design requirements; or, the sensor package structure 100 can be produced by implementing a method other than the manufacturing method S200 that is provided by the present embodiment.

Moreover, the specific implementations of the connecting step S240 and the slicing step S250 in the present embodiment are substantially identical to that of the connecting step S130 and the slicing step S140 of the first embodiment, but the present disclosure is not limited thereto. In addition, the connecting step S240 and the slicing step S250 in the present embodiment are arranged between the cutting step S230 and the chip-bonding step S260, but the present disclosure is not limited thereto. In other words, the connecting step S240 and the slicing step S250 are only required to be implemented before the chip-bonding step S260 according to practical requirements.

As shown in FIG. 13 to FIG. 15, the preparing step S210 is implemented by placing a mold 200 onto a light-permeable layer 70 along a height direction H to jointly define a formation space 201. In the present embodiment, the light-permeable sheet 7 can be a flat glass sheet and preferably has a broadband anti-reflection (BBAR) coating film formed on an outer surface thereof, but the present disclosure is not limited thereto.

Specifically, the light-permeable layer 70 defines a plurality of light-permeable sheets 7. The light-permeable sheets 7 in the present embodiment are connected to each other and are in a matrix arrangement, and the formation space 201 has a plurality of sub-spaces 2011 in spatial communication with each other, but the present disclosure is not limited thereto. For example, in other embodiments of the present disclosure not shown in the drawings, the light-permeable sheets 7 cannot be in a matrix arrangement; or, the sub-spaces 2011 of the formation space 201 are isolated from each other (i.e., the sub-spaces 2011 are not in spatial communication with each other).

Moreover, the mold 200 in the present embodiment has a plurality of side walls 202, and each of the side walls 202 and the height direction H have a demolding angle σ202 therebetween that is within a range from 5 degrees to 7 degrees, thereby facilitating a demolding process in the following molding step S220. Specifically, a distance between any two of the side walls 202 in one of the sub-spaces 2011 gradually decreases in a direction away from the light-permeable layer 70.

The molding step S220 is implemented by injecting an adhesive into the formation space 201 to form a frame layer 20 on the light-permeable layer 70. In the present embodiment, the frame layer 20 defines a plurality of ring-shaped molding frames 2 that are connected to each other, but the present disclosure is not limited thereto. For example, in other embodiments of the present disclosure not shown in the drawings, the ring-shaped molding frames 2 can be separated from each other. In other words, each of the sub-spaces 2011 is provided with one of the ring-shaped molding frames 2 formed therein.

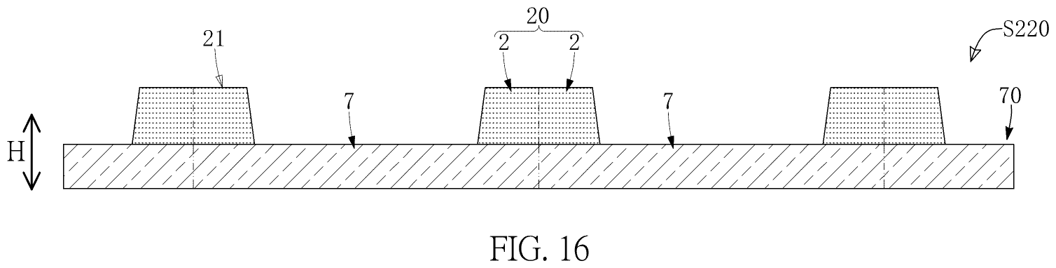

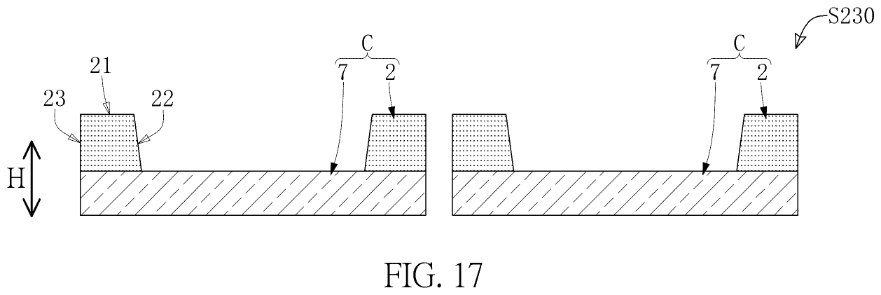

As shown in FIG. 13, FIG. 16, and FIG. 17, the cutting step S230 is implemented by cutting the light-permeable layer 70 and the frame layer 20 to form the light-permeable sheets 7 separated from each other and the ring-shaped molding frames 2 that are separated from each other and that are respectively fixed on the light-permeable sheets 7. Moreover, each of the light-permeable sheets 7 and the corresponding ring-shaped molding frame 2 fixed thereon are jointly defined as a cap C, and each of the ring-shaped molding frames 2 has a connection end 21 arranged away from the corresponding light-permeable sheet 7.

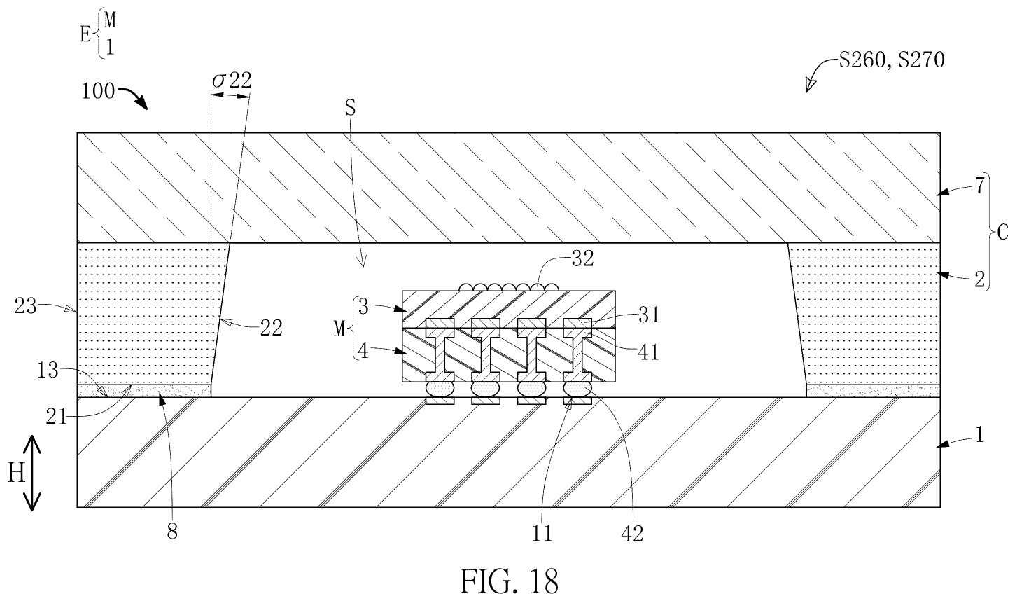

As shown in FIG. 13 and FIG. 18, the chip-bonding step S260 is implemented by mounting a sensing module M onto a chip-bonding region 11 of a substrate 1 to be jointly formed as a CoWoS component E. The sensing module M includes an interposer 4 stacked and mounted on the chip-bonding region 11 and a sensor chip 3 that is stacked and mounted on the interposer 4. Moreover, the interposer 4 of the sensing modules M is provided with a plurality of solder balls 42 disposed on a bottom surface thereof, and the sensing modules M is mounted on the chip-bonding region 11 of the substrate 1 through the solder balls 42.

It should be noted that the manufacturing method S200 is limited to using the CoWoS component E for achieving the wireless configuration, thereby reducing a distance between a sensing region 32 and an outer edge of the sensor chip 3 (e.g., the sensor chip 3 of the CoWoS component E is provided without any pad on the top surface thereof, such that the distance can be reduced to be less than 200 μm). Accordingly, any manufacturing method not using the CoWoS component is different from the manufacturing method S200 provided by the present embodiment.

As shown in FIG. 13 and FIG. 18, the packaging step S270 is implemented by adhering the connection end 21 of the cap C onto the substrate 1, such that the substrate 1 and the cap C jointly define an enclosed space S that receives the sensing module M therein, thereby forming the sensor package structure 100. The connection between the connection end 21 of the cap C and the substrate 1 in the sensor package structure 100 is established through an adhesive layer 8, and the adhesive layer 8 can be a light-curing glue (e.g., a UV glue), a thermal-curing glue, or an adhesive sheet, but the present disclosure is not limited thereto.

In other embodiments of the present disclosure not shown in the drawings, the chip-bonding step S260 can be implemented by respectively mounting a plurality of sensing modules M onto a plurality of substrates 1 of a substrate layer, and after the packaging step S270 is implemented, the substrate layer is sliced to form the substrates 1 separated from each other, thereby obtaining a plurality of sensor package structures 100.

In summary, the above description of the present embodiment substantially describes an exemplary implementation of the manufacturing method S200, and the following description substantially describes the sensor package structure 100 produced by implementing the manufacturing method S200. In other words, at least part of features of the sensor package structure 100 can be referred to in the above description of the manufacturing method S200, but the present disclosure is not limited thereto.

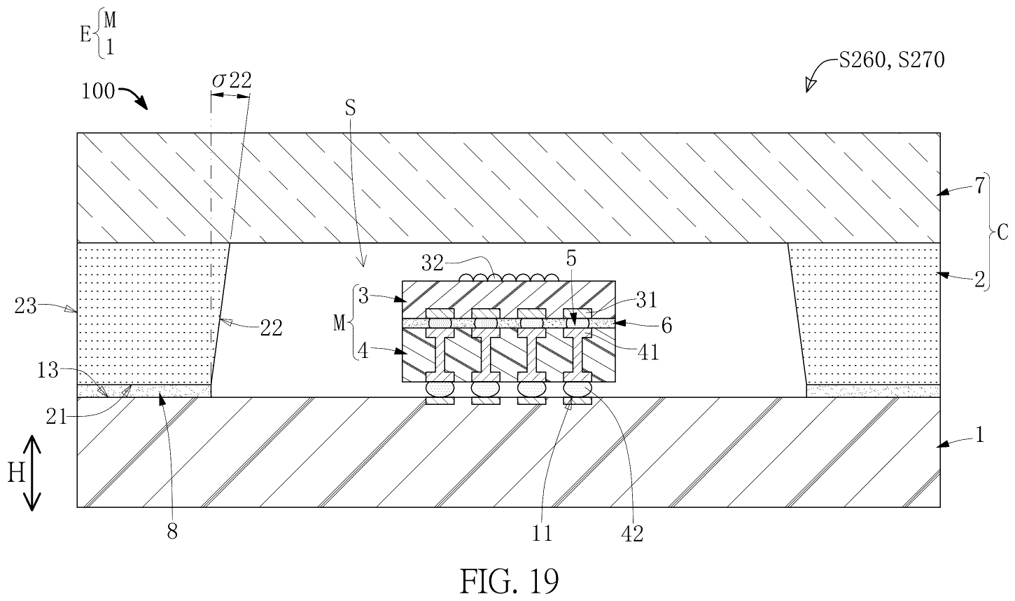

As shown in FIG. 18 and FIG. 19, the sensor package structure 100 includes a substrate 1, a sensing module M mounted on the substrate 1, and a cap C that is fixed to the substrate 1. The substrate 1 is flat and has a chip-bonding region 11 and a connection region 13 that surrounds the chip-bonding region 11 and that has a rectangular ring-shape.

The sensing module M includes an interposer 4 and a sensor chip 3 that is stacked and mounted on the interposer 4. The sensing module M is stacked and mounted on the chip-bonding region 11 through the interposer 4, such that the sensing module M and the substrate 1 are jointly formed as a CoWoS component E. The assembling manner of the sensor chip 3 and the interposer 4 can be adjusted or changed according to practical requirements.

For example, as shown in FIG. 18, connection pads 31 of the sensor chip 3 and contacts 41 of the interposer 4 are fixed and electrically coupled to each other in a hybrid bonding manner. Or, as shown in FIG. 19, the sensing module M includes a plurality of micro-bumps 5 and an underfill layer 6, the micro-bumps 5 and the underfill layer 6 are arranged between the sensor chip 3 and the interposer 4, the sensor chip 3 and the interposer 4 are electrically coupled to each other through the micro-bumps 5, and the micro-bumps 5 are embedded in the underfill layer 6.

The cap C includes a light-permeable sheet 7 and a ring-shaped molding frame 2 that is formed on the light-permeable sheet 7, and the ring-shaped molding frame 2 has a connection end 21 arranged away from the light-permeable sheet 7. The cap C defines a height direction H perpendicular to the light-permeable sheet 7, an inner side surface 22 of the ring-shaped molding frame 2 and the height direction H have a slanting angle σ22 therebetween that is within a range from 5 degrees to 7 degrees, and an outer side surface 23 of the ring-shaped molding frame 2 is coplanar with an outer edge of the light-permeable sheet 7.

Moreover, the cap C is adhered and fixed to the connection region 13 of the substrate 1 through the connection end 21, such that the substrate 1 and the cap C jointly define an enclosed space S that receives the sensing module M therein. The sensing module M is preferably spaced apart from the inner side surface 22 of the ring-shaped molding frame 2, and is spaced apart from the light-permeable sheet 7.

The connection between the connection end 21 of the cap C and the connection region 13 of the substrate 1 in the sensor package structure 100 is established through an adhesive layer 8, and the adhesive layer 8 can be a light-curing glue (e.g., a UV glue), a thermal-curing glue, or an adhesive sheet, but the present disclosure is not limited thereto.

### Beneficial Effects of the Embodiments

In conclusion, the sensor package structure and the manufacturing method thereof in the present disclosure can be provided with the wireless configuration through the CoWoS component, thereby reducing a distance between the sensing region and the outer edge of the sensor chip (e.g., the sensor chip of the CoWoS component is provided without any pad on the top surface thereof, such that the distance can be reduced to be less than 200 μm), and effectively avoiding defects caused by metal wires.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A manufacturing method of a sensor package structure having a wireless configuration, the manufacturing method comprising:
a preparing step implemented by placing a mold onto a substrate layer to jointly define a formation space, wherein the substrate layer defines a plurality of substrates;
a molding step implemented by injecting an adhesive into the formation space to form a frame layer on the substrate layer, wherein the frame layer defines a plurality of ring-shaped molding frames respectively formed on the substrates, and each of the substrates and a corresponding one of the ring-shaped molding frames are jointly defined as one of a plurality of carrying bases, and wherein, in each of the carrying bases, the substrate has a chip-bonding region surrounded by the ring-shaped molding frame, and the ring-shaped molding frame has a connection end arranged away from the substrate;
a chip-bonding step implemented by respectively mounting a plurality of sensing modules onto the chip-bonding regions of the substrates, such that each of the sensing modules and a corresponding one of the substrates are jointly formed as a CoWoS (chip on wafer on substrate) component, wherein each of the sensing modules includes an interposer stacked and mounted on the chip-bonding region of the corresponding substrate and a sensor chip that is stacked and mounted on the interposer;
a packaging step implemented by respectively adhering a plurality of light-permeable sheets onto the connection ends of the carrying bases, such that each of the carrying bases and a corresponding one of the light-permeable sheets jointly define an enclosed space that receives a corresponding one of the sensing modules therein; and
a cutting step implemented by cutting the substrate layer and the frame layer to separate the carrying bases from each other.

2. The manufacturing method according to claim 1, wherein at least one of the sensing modules includes a plurality of micro-bumps and an underfill layer, the micro-bumps and the underfill layer are arranged between the sensor chip and the interposer, the sensor chip and the interposer are electrically coupled to each other through the micro-bumps, and the micro-bumps are embedded in the underfill layer.

3. The manufacturing method according to claim 1, wherein, in at least one of the sensing modules, connection pads of the sensor chip and contacts of the interposer are fixed and electrically coupled to each other in a hybrid bonding manner.

4. The manufacturing method according to claim 1, wherein, before the chip-bonding step, the manufacturing method further includes:
a connecting step implemented by mounting a wafer onto an interposer layer, wherein the wafer defines the sensor chips in a matrix arrangement, the interposer layer defines the interposers, and the sensor chips are respectively stacked and mounted onto the interposers; and
a slicing step implemented by slicing the interposer layer and the wafer to form the interposers separated from each other and the sensor chips that are respectively fixed to the interposers, wherein each of the interposers and a corresponding one of the sensor chips are jointly defined as one of the sensing modules.

5. The manufacturing method according to claim 1, wherein, in the chip-bonding step, the interposer of each of the sensing modules is provided with a plurality of solder balls disposed on a bottom surface thereof, and each of the sensing modules is mounted on the chip-bonding region of the corresponding carrying base through the solder balls.

6. The manufacturing method according to claim 1, wherein, in the preparing step, the mold is disposed on the substrate layer along a height direction, the mold has a plurality of side walls, and each of the side walls and the height direction have a demolding angle therebetween that is within a range from 5 degrees to 7 degrees.

7. A sensor package structure having a wireless configuration, comprising:
a carrying base including:
a substrate having a chip-bonding region and a molding region that surrounds the chip-bonding region; and
a ring-shaped molding frame formed on the molding region of the substrate, wherein the ring-shaped molding frame has a connection end arranged away from the substrate;
a sensing module including an interposer stacked and mounted on the chip-bonding region and a sensor chip that is stacked and mounted on the interposer, wherein the sensing module and the substrate are jointly formed as a CoWoS component; and
a light-permeable sheet adhered and fixed to the connection end of the carrying base, wherein the carrying base and the light-permeable sheet jointly define an enclosed space that receives the sensing module therein.

8. The sensor package structure according to claim 7, wherein the sensing module includes a plurality of micro-bumps and an underfill layer, the micro-bumps and the underfill layer are arranged between the sensor chip and the interposer, the sensor chip and the interposer are electrically coupled to each other through the micro-bumps, and the micro-bumps are embedded in the underfill layer.

9. The sensor package structure according to claim 7, wherein connection pads of the sensor chip and contacts of the interposer are fixed and electrically coupled to each other in a hybrid bonding manner.

10. The sensor package structure according to claim 7, wherein the carrying base defines a height direction perpendicular to the chip-bonding region, an inner side surface of the ring-shaped molding frame and the height direction have a slanting angle therebetween that is within a range from 5 degrees to 7 degrees, and an outer side surface of the ring-shaped molding frame is coplanar with an outer edge of the substrate.

11. A manufacturing method of a sensor package structure having a wireless configuration, the manufacturing method comprising:
a preparing step implemented by placing a mold onto a light-permeable layer to jointly define a formation space;
a molding step implemented by injecting an adhesive into the formation space to form a frame layer on the light-permeable layer;
a cutting step implemented by cutting the light-permeable layer and the frame layer to form a plurality of light-permeable sheets separated from each other and a plurality of ring-shaped molding frames that are respectively fixed on the light-permeable sheets, wherein each of the light-permeable sheets and a corresponding one of the ring-shaped molding frames are jointly defined as a cap, and each of the ring-shaped molding frames has a connection end arranged away from the corresponding light-permeable sheet;
a chip-bonding step implemented by mounting a sensing module onto a chip-bonding region of a substrate to be jointly formed as a CoWoS (chip on wafer on substrate) component, wherein the sensing module includes an interposer stacked and mounted on the chip-bonding region and a sensor chip that is stacked and mounted on the interposer; and
a packaging step implemented by adhering the connection end of the cap onto the substrate, such that the substrate and the cap jointly define an enclosed space that receives the sensing module therein.

12. The manufacturing method according to claim 11, wherein the sensing module includes a plurality of micro-bumps and an underfill layer, the micro-bumps and the underfill layer are arranged between the sensor chip and the interposer, the sensor chip and the interposer are electrically coupled to each other through the micro-bumps, and the micro-bumps are embedded in the underfill layer.

13. The manufacturing method according to claim 11, wherein connection pads of the sensor chip and contacts of the interposer are fixed and electrically coupled to each other in a hybrid bonding manner.

14. The manufacturing method according to claim 11, wherein, before the chip-bonding step, the manufacturing method further includes:
a connecting step implemented by mounting a wafer onto an interposer layer, wherein the wafer defines the sensor chips in a matrix arrangement, the interposer layer defines the interposers, and the sensor chips are respectively stacked and mounted onto the interposers; and
a slicing step implemented by slicing the interposer layer and the wafer to form the interposers separated from each other and the sensor chips that are respectively fixed to the interposers, wherein each of the interposers and a corresponding one of the sensor chips are jointly defined as one of the sensing modules.

15. The manufacturing method according to claim 11, wherein, in the chip-bonding step, the interposer of the sensing modules is provided with a plurality of solder balls disposed on a bottom surface thereof, and the sensing module is mounted on the chip-bonding region of the substrate through the solder balls.

16. The manufacturing method according to claim 11, wherein, in the preparing step, the mold is disposed on the light-permeable layer along a height direction, the mold has a plurality of side walls, and each of the side walls and the height direction have a demolding angle therebetween that is within a range from 5 degrees to 7 degrees.

17. A sensor package structure having a wireless configuration, comprising:
a substrate having a chip-bonding region and a connection region that surrounds the chip-bonding region;
a sensing module including an interposer mounted on the chip-bonding region and a sensor chip that is stacked and mounted on the interposer, wherein the sensing module and the substrate are jointly formed as a CoWoS component; and
a cap including:
a light-permeable sheet; and
a ring-shaped molding frame formed on the light-permeable sheet, wherein the ring-shaped molding frame has a connection end arranged away from the light-permeable sheet;
wherein the connection end of the light-permeable sheet is adhered and fixed to the connection region of the substrate, and wherein the substrate and the cap jointly define an enclosed space that receives the sensing module therein.

18. The sensor package structure according to claim 17, wherein the sensing module includes a plurality of micro-bumps and an underfill layer, the micro-bumps and the underfill layer are arranged between the sensor chip and the interposer, the sensor chip and the interposer are electrically coupled to each other through the micro-bumps, and the micro-bumps are embedded in the underfill layer.

19. The sensor package structure according to claim 17, wherein connection pads of the sensor chip and contacts of the interposer are fixed and electrically coupled to each other in a hybrid bonding manner.

20. The sensor package structure according to claim 17, wherein the cap defines a height direction perpendicular to the light-permeable sheet, an inner side surface of the ring-shaped molding frame and the height direction have a slanting angle therebetween that is within a range from 5 degrees to 7 degrees, and an outer side surface of the ring-shaped molding frame is coplanar with an outer edge of the light-permeable sheet.
